(19) United States
(12) Patent Application Publication
(10) Pub. No.: US 2017/0110598 A1
(43) Pub. Date: Apr. 20, 2017

(54) FIELD EFFECT DIODE AND METHOD OF MANUFACTURING THE SAME

(71) Applicant: Gpower Semiconductor, Inc., Suzhou (CN)

(72) Inventor: Hongwei CHEN, Suzhou (CN)

(21) Appl. No.: 15/390,539

(22) Filed: Dec. 26, 2016

Related U.S. Application Data
(63) Continuation of application No. PCT/CN2015/075970, filed on Apr. 7, 2015.

(30) Foreign Application Priority Data
Sep. 5, 2014 (CN) 201410452104.6

(51) Int. Cl. H01L 29/872; H01L 29/66; H01L 29/778; H01L 29/47

(52) U.S. Cl. CPC H01L 29/872; H01L 29/475; H01L 29/66462; H01L 29/7789; H01L 29/66143

(57) ABSTRACT

A field effect diode comprises: a substrate; a nucleation layer, a back barrier layer, a channel layer, a first barrier layer and a second barrier layer sequentially located on the substrate; and an anode and a cathode located on the second barrier layer, wherein a groove is formed in the second barrier layer, two-dimensional electron gas is formed at an interface between the first barrier layer and the channel layer except for a part of the interface under the groove when a reverse bias voltage or no external voltage is applied to the field effect diode, and is formed at all parts of the interface when a forward bias voltage is applied to the field effect diode.

### CROSS-REFERENCE TO RELATED APPLICATIONS

This application is a continuation of international application No. PCT/CN2015/075970 filed on Apr. 7, 2015, which claims the benefit and priority of Chinese patent application No. 201410452104.6 filed on Sep. 5, 2014. Both applications are incorporated herein in their entirety by reference.

### TECHNICAL FIELD

The disclosed embodiments relate to semiconductor technology, and more particularly, to a field effect diode and a method of manufacturing the same.

### BACKGROUND

Currently, power electronics technology in the fields of high-voltage power supply, power conversion, factory automation, energy management of motor vehicles and so on are rapidly developing. As switches or rectifiers in circuit systems, power semiconductor devices play an important role in power electronics technology. Power devices greatly impact consumption and efficiency of circuit systems, thus have important impact on environments, such as energy saving. In recent years, GaN Schottky diodes have drawn great intention in the industry due to their excellent performance advantages such as high frequency, high power density and low power consumption.

GaN has a large bandgap width which can be up to 3.4 eV at room temperature, and also has the characteristics of high electron mobility, high thermal conductivity and the ability of withstanding high temperature and high voltage. Two-dimensional electron gas (2DEG) having a density of 10¹³ cm⁻² or more can be easily formed at AlGaN/GaN heterojunction interface even in an undoped state. This is because of existence of spontaneous polarization and piezoelectric polarization in the AlGaN/GaN structure. A polarized electric field induces 2DEG with high concentration and high mobility in a GaN layer at the AlGaN/GaN interface. The critical breakdown voltage of GaN is nearly one order of magnitude higher than that of Si, and the forward on-resistance of the corresponding Schottky diode is about three orders of magnitude lower than that of a Si device. Therefore, in the fields of power devices requiring high temperature, high switching speed and high voltage, GaN devices are ideal substitutes for Si devices.

Diode devices for high voltage conversion circuits should have the following characteristics. When reverse biased, i.e., a cathode has a higher voltage than an anode, a Schottky diode can withstand a relatively high voltage while a reverse leakage current thereof should be maintained at a low level. When forward biased, the diode should have a forward voltage drop and a forward on-resistance as low as possible to reduce turn-on losses. On the other hand, the amount of minority carrier charges stored in the diode should be as small as possible to reduce switching losses caused by recombination of the minority carrier charges when the diode is changed to a turn-off state from a turn-on state, thereby improving efficiency. In a diode, the different performance parameters described above are constrained to each other. For example, a low Schottky barrier height reduces a forward voltage drop of a Schottky diode and increases a current density when the diode is forward turned-on, however increases a reverse leakage current of the Schottky diode. Furthermore, the low barrier height degrades electrical properties of the Schottky diode at high temperatures, e.g., a breakdown voltage thereof is decreased. In contrast, a high Schottky barrier height helps reduce the reverse leakage current, however results in a large forward voltage drop (V_{F}), which increases turn-on losses.

Therefore, in view of the above-described technical problems, it is required to provide a field effect diode having a low forward turn-on voltage drop, a low reverse leakage current and a high breakdown voltage, and a method of manufacturing the same.

### SUMMARY

In view of this, embodiments of the present invention are directed to a field effect diode having a low forward turn-on voltage drop, a low reverse leakage current and a high breakdown voltage. Embodiments of the present invention are also directed to a method of manufacturing such a field effect diode.

According to one or more embodiments of the present invention, there is provided a field effect diode, comprising: a substrate; a nucleation layer located on the substrate; a back barrier layer located on the nucleation layer; a channel layer located on the back barrier layer; a first barrier layer located on the channel layer; a second barrier layer located on the first barrier layer; and an anode and a cathode located on the second barrier layer, wherein a groove is formed in the second barrier layer, the cathode is made of a first ohmic contact electrode, the anode is made of a composite structure comprising a second ohmic contact electrode and a Schottky electrode which is located in the groove and has a short circuit connection with the second ohmic contact electrode; wherein two-dimensional electron gas is formed at an interface between the first barrier layer and the channel layer except for a part of the interface under the groove when a reverse bias voltage or no external voltage is applied to the field effect diode, and is formed at all parts of the interface when a forward bias voltage is applied to the field effect diode.

In an embodiment, each of the back barrier layer, the first barrier layer and the second barrier layer is formed of AlGaN, the channel layer is formed of GaN, difference between an Al component content of the back barrier layer and that of the first barrier layer is zero or no more than 5%, an Al component content of the second barrier layer is higher than that of the back barrier layer and that of the first barrier layer. The Al component content of the back barrier layer is 10%-15%, the Al component content of the first barrier layer is 10%-15%, and the Al component content of the second barrier layer is 20%-40%.

In an embodiment, a sidewall of the groove has an inclination, a depth of the groove is equal to a thickness of the second barrier layer.

In an embodiment, the field effect diode further comprises a passivation layer located on the second barrier layer.

In an embodiment, the field effect diode further comprises an etching stop layer between the first barrier layer and the second barrier layer, wherein the etching stop layer has an etching rate lower than that of the first barrier layer.

In an embodiment, the field effect diode further comprises an insulating layer located on the second barrier layer and a part of the Schottky electrode, and a field plate which is located on the anode and covers a part of the insulation layer.

In an embodiment, the field effect diode further comprises an insulating dielectric layer formed on a lower surface of the Schottky electrode.

In an embodiment, the first barrier layer has a thickness less than 15 nm.

In an embodiment, the back barrier layer has a thickness of 1-3.5 μm.

In an embodiment, the field effect diode further comprises a buffer layer between the nucleation layer and the back barrier layer. The buffer layer has a thickness of 1-3.5 μm, the back barrier layer has a thickness of 50-100 nm, the channel layer has a thickness of 15-35 nm, the first barrier layer has a thickness of 15-45 nm, and the second barrier layer has a thickness of 25-40 nm.

According to one or more embodiments of the present invention, there is also provided a method of manufacturing a field effect diode, comprising: preparing a substrate; forming a nucleation layer on the substrate; forming a back barrier layer on the nucleation layer; forming a channel layer on the back barrier layer; forming a first barrier layer on the channel layer; forming a second barrier layer on the first barrier layer and a groove in the second barrier layer; and forming an anode and a cathode on the second barrier layer, the cathode being made of a first ohmic contact electrode, the anode being made of a composite structure comprising a second ohmic contact electrode and a Schottky electrode which is located in the groove and has a short circuit connection with the second ohmic contact electrode, wherein two-dimensional electron gas is formed at an interface between the first barrier layer and the channel layer except for a part of the interface under the groove when a reverse bias voltage or no external voltage is applied to the field effect diode, and is formed at all parts of the interface when a forward bias voltage is applied to the field effect diode.

In an embodiment, each of the back barrier layer, the first barrier layer and the second barrier layer is formed of AlGaN, the channel layer is formed of GaN, difference between an Al component content of the back barrier layer and that of the first barrier layer is zero or no more than 5%, an Al component content of the second barrier layer is higher than that of the back barrier layer and that of the first barrier layer. The Al component content of the back barrier layer is 10%-15%, the Al component content of the first barrier layer is 10%-15%, and the Al component content of the second barrier layer is 20%-40%.

In an embodiment, a sidewall of the groove has an inclination, and a depth of the groove is equal to a thickness of the second barrier layer.

In an embodiment, the method further comprises forming a passivation layer on the second barrier layer.

In an embodiment, the method further comprises forming an etching stop layer having an etching rate lower than that of the first barrier layer on the first barrier layer.

In an embodiment, the method further comprises forming a buffer layer on the nucleation layer.

Compared with the prior art, when the field effect diode according to an embodiment of the present invention is forward biased, the 2DEG will be induced at the part of the interface between the channel layer and the first barrier layer under the groove by applying a low bias voltage to the anode. Since the diode is turned-on in the horizontal direction by the 2DEG with high concentration and high mobility, the diode has a low forward voltage drop and a low on-resistance. When the field effect diode according to an embodiment of the present invention is reverse biased, the channel is blocked since the 2DEG under the groove is depleted completely, so that the electrons cannot flow between the cathode and the anode under a reverse bias voltage, which lowers the reverse leakage current.

In addition, the back barrier layer with good crystal quality can form a barrier with the channel layer thereon. Due to the existence of the barrier, electrons are difficult to enter into the back barrier layer from the channel layer when the diode is reverse biased, which cuts off the leakage current of the buffer layer of the diode, so that the reverse leakage current of the field effect diode is maintained at a relatively low level. Therefore, the ability of the diode to withstand a reverse voltage is increased, which increases the reverse breakdown voltage of the diode.

Furthermore, according to an embodiment of the present invention, the Schottky electrode in the groove has an inclination. When the diode is reverse biased, the distribution of electric field lines at an edge of the anode metal can be modulated, the electric field peak at the edge of the anode can be reduced, thereby improving the breakdown voltage of the diode.

### BRIEF DESCRIPTION OF DRAWINGS

These and other aspects will become apparent and more readily appreciated from the following description of the embodiments, taken in conjunction with the accompanying drawings in which:

FIG. 1(a) is a schematic structural view of a field effect diode according to a first embodiment of the present invention;

FIG. 1(b) is a schematic view illustrating band distribution in a horizontal direction (a direction when a current flows) near a two-dimensional electron gas depletion region when no voltage is applied to a channel layer of the field effect diode according to the first embodiment of the present invention;

FIG. 1(c) is a schematic view illustrating band distribution in the horizontal direction (the direction when the current flows) near the two-dimensional electron gas depletion region when a reverse bias voltage is applied to the channel layer of the field effect diode according to the first embodiment of the present invention;

FIG. 1(d) is a schematic view illustrating band distribution in the horizontal direction (the direction when the current flows) near the two-dimensional electron gas depletion region when a forward bias voltage is applied to the channel layer of the field effect diode according to the first embodiment of the present invention;

FIG. 1(e) is a diagram illustrating an I-V characteristic of the field effect diode according to the first embodiment of the present invention;

FIG. 2 is a schematic structural view of a field effect diode according to a second embodiment of the present invention;

FIG. 3 is a schematic structural view of a field effect diode according to a third embodiment of the present invention;

FIG. 4 is a schematic structural view of a field effect diode according to a fourth embodiment of the present invention;

FIG. 5 is a schematic structural view of a field effect diode according to a fifth embodiment of the present invention;

FIG. 6 is a schematic structural view of a field effect diode according to a sixth embodiment of the present invention; and

FIG. 7 is a schematic structural view of a field effect diode according to a seventh embodiment of the present invention.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description.

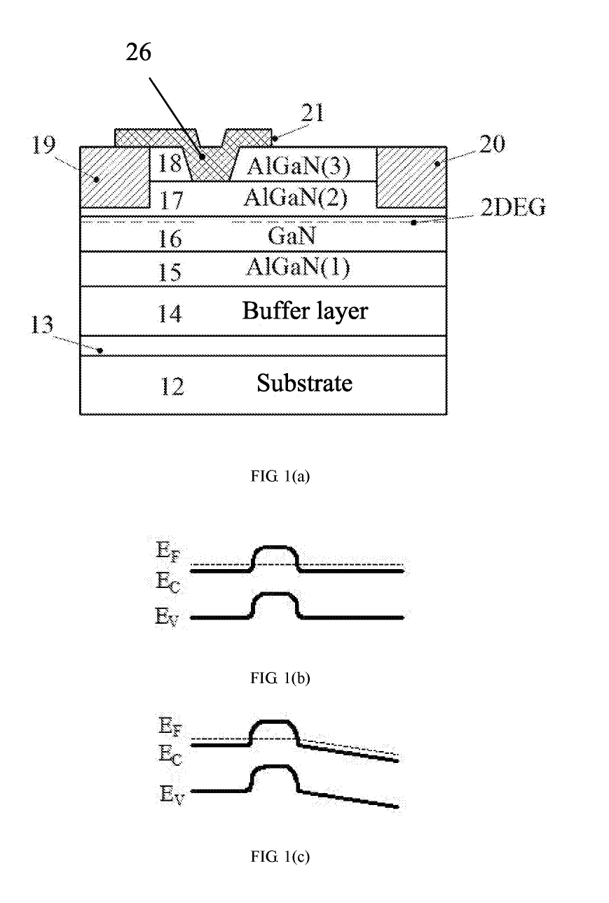

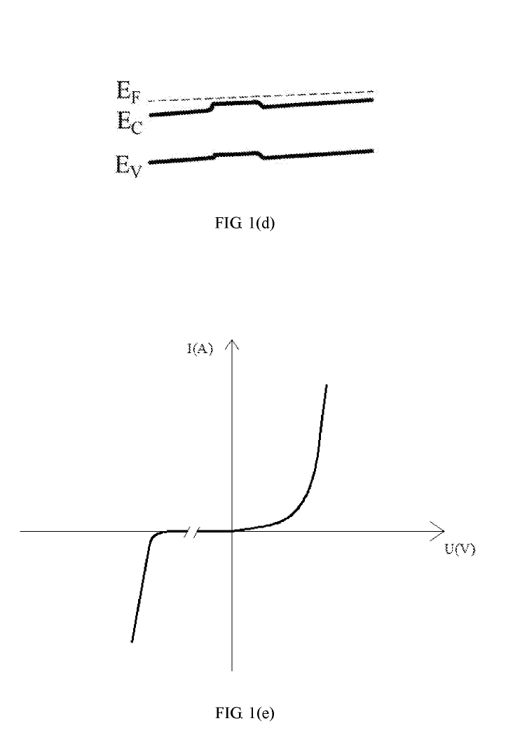

Hereinafter a field effect diode according to a first embodiment of the present invention will be described with reference to FIGS. 1(a) to 1(e).

FIG. 1(a) is a schematic structural view of a field effect diode according to a first embodiment of the present invention. As shown in FIG. 1(a), the field effect diode according to the first embodiment of the present invention includes a substrate 12, a nucleation layer 13, a buffer layer 14, a back barrier layer 15, a channel layer 16, a first barrier layer 17, a second barrier layer 18, an anode ohimic contact electrode 19, a cathode ohimic contact electrode 20 and a Schottky electrode 21.

The substrate 12 is typically formed of sapphire, SiC or Si. The nucleation layer 13, the buffer layer 14, the back barrier layer 15, the channel layer 16, the first barrier layer 17 and the second barrier layer 18 are sequentially formed on the substrate 12. Two ohmic contacts on the second barrier layer 18 form the anode ohimic contact electrode 19 and the cathode ohimic contact electrode 20 of the field effect diode respectively. Between the anode ohimic contact electrode 19 and the cathode ohimic contact electrode 20, a groove 26 with a certain inclination is etched in the second barrier layer 18. A bottom surface of the groove 26 reaches an interface between the first barrier layer 17 and the second barrier layer 18. The Schottky electrode 21 is formed in the groove 26, and is short-circuited with the anode ohimic contact electrode 19 to form a diode anode structure collectively.

In the present embodiment, each of the back barrier layer 15, the first barrier layer 17 and the second barrier layer 18 is formed of AlGaN, while the channel layer 16 is formed of GaN. The back barrier layer 15 has a thickness of 1-3.5 μm, the channel layer 16 has a thickness of 15-35 nm, the first barrier layer 17 has a thickness of 15-45 nm, and the second barrier layer 18 has a thickness of 25-45 nm.

Furthermore, an Al component content of the second barrier layer 18 is higher than that of the first barrier layer 17, the difference between the Al composition content of the first barrier layer 17 and that of the back barrier layer 15 is zero or within 5%. Preferably, each of the Al component content of the back barrier layer 15 and that of the first barrier layer 17 is 10%-15% by mass, and the Al component content of the second barrier layer 18 is 20%-40% by mass.

Since both the back barrier layer 15 and the first barrier layer 17 are formed of AlGaN and they have close Al component contents, the two layers have close lattice constants. In addition, since the channel layer 16 between the back barrier layer 15 and the first barrier layer 17 has a small thickness, a lattice constant of the channel layer 16 formed of GaN is substantially equal to that of the back barrier layer 15 and close to that of the first barrier layer 17. Chargers formed at an interface between the back barrier layer 15 and the GaN channel layer 16 have the same polarized charge density as those formed at an interface between the first barrier layer 17 and the GaN channel layer 16, but they have opposite charge properties, thus have counteracted effects. Therefore, 2DEG will not be formed at a part of the GaN channel 16 under the groove 26, instead, a depletion channel will be formed at that part. Under this state, band distribution in a horizontal direction (a direction when a current flows) at the interface between the GaN channel layer 16 and the first barrier layer 17 is shown in FIG. 1(b) in which E_{F}, E_{C} and E_{V} represent Fermi level, conduction band bottom and valence band top respectively. It can be seen from FIG. 1(b) that the 2DEG in the part of the channel layer 16 under the groove 26 is depleted so that an electron barrier is formed. When applied a reverse bias voltage, electrons cannot pass through the barrier, so that the 2DEG channel is blocked.

The second barrier layer 18 formed of AlGaN has a higher Al component content than that of the back barrier layer 15 and that of the first barrier layer 17, and thus has a lower lattice constant than that of the lower first barrier layer 17 and that of the channel layer 16 thereunder. Therefore, there are both of a spontaneous polarization electric field and a piezoelectric polarization electric field in a part of the second barrier layer 18 where the groove 26 is not formed. The polarized electric fields induce 2DEG at the interface between the first barrier layer 17 and the channel layer 16. Accordingly, the 2DEG in a part of the interface between the first barrier layer 17 and the channel layer 16 under the groove 26 will be depleted completely while the 2DEG will exist in the other part of the interface.

Since the 2DEG under the groove 26 is depleted completely so that the channel is blocked, when a reverse bias voltage is applied, a 2DEG depletion region in a part of the channel under an edge of the cathode electrode 20 adjacent to the Schottky electrode 21 will be widened, thereby suppressing the reverse leakage current. Under this state, band distribution in the horizontal direction (the direction when the current flows) at the interface between the GaN channel layer 16 and the first barrier layer 17 is shown in FIG. 1(c). It can be seen from FIG. 1(c) that the electrons cannot pass through the barrier so that the diode is turned off. Furthermore, the back barrier layer 15 makes it difficult for the electrons enter into the buffer layer 14 from the channel layer 16, so a leakage current in the buffer layer 15 is cut off. Such a structure enables the diode to withstand a relatively large reverse bias voltage.

When a forward bias voltage is applied, on one hand, the 2DEG channel under the groove 26 can be recovered partly or fully by a positive Schottky voltage. Under this state, band distribution in the horizontal direction (the direction when the current flows) at the interface between the GaN channel layer 16 and the first barrier layer 17 is shown in FIG. 1(d). It can be seen from FIG. 1(d) that the electron barrier height is decreased to below the Fermi level, the electrons can flow to the anode ohmic metal from the cathode ohmic metal and thus the diode is turned-on. On the other hand, the Schottky electrode itself will be turned-on and thus can conduct under a certain forward bias voltage. These two currents form a forward current of the diode collectively, which reduces the forward turn-on voltage and the forward on-resistance of the diode. Therefore, the field effect diode has a forward turn-on characteristic, and the I-V characteristic thereof is shown in FIG. 1(e).

As a summary, when a reverse bias voltage or no external voltage is applied to the field effect diode, 2DEG is not formed at a part of the interface between the first barrier layer 17 and the channel layer 16 under the grove 26 while is formed at the other part of the interface. When a forward bias voltage is applied to the field effect diode, 2DEG is formed at all parts of the interface between the first barrier layer 17 and the channel layer 16.

In an embodiment, a sidewall of the groove 26 has a certain inclination. The Schottky electrode 21 is formed in the groove 26 having a certain inclination, which introduces a gate field plate. Therefore, the electric field near edges of the anode electrode can be modulated and a high breakdown voltage can be obtained.

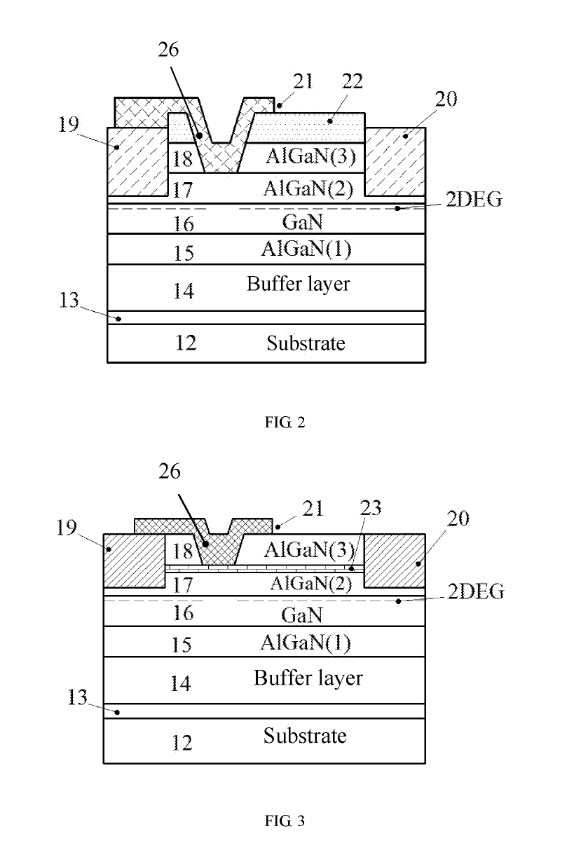

FIG. 2 is a schematic structural view of a field effect diode according to a second embodiment of the present invention. The duplicated description on the same or similar elements as those in the first embodiment will not be repeated.

As shown in FIG. 2, a passivation layer 22 is further formed on the second barrier layer 18. In this case, the groove 26 is formed in both of the second barrier layer 18 and the passivation layer 22. The passivation layer 22 serves to passivate the surface of the diode device, suppress the current collapse effect of the device, and reduce the degradation of the dynamic characteristics of the diode. The passivation layer 22 may be formed of any of silicon nitride, alumina, silica, zirconia, hafnium oxide and an organic polymer or any combination thereof.

If the diode device is not passivated, when a reverse bias voltage is applied to the diode, the surface state at a side of the Schottky electrode adjacent to the cathode will capture electrons. The introduction of negative charges on the surface will deplete 2DEG completely. Since the bandgap width of the gallium nitride material reaches up to 3.4 eV and the bandgap width of AlGaN is between 3.4 eV and 6.2 eV (AlN), which varies depend on the Al composition, some surface states with deep energy level positions will not be released in a long time after capturing electrons. The introduced negative charges still make the 2DEG partially depleted, resulting in increase of the forward on-resistance of the diode. By introducing the passivation layer, the current collapse effect can be eliminated and the dynamic performance of the diode can be improved.

FIG. 3 is a schematic structural view of a field effect diode according to a third embodiment of the present invention. The duplicated description on the same or similar elements as those in the first embodiment will not be repeated.

As shown in FIG. 3, an etching stop layer 23 is further interposed between the first barrier layer 17 and the second barrier layer 18. The etching stop layer 23 is usually formed of a material which has slower etching rate than that of AlGaN, such as AlN, to accurately control the position where the etching stops to ensure it at the interface between the second barrier layer 18 and the first barrier layer 17, thereby simplifying the implementation of processes and improving the yield.

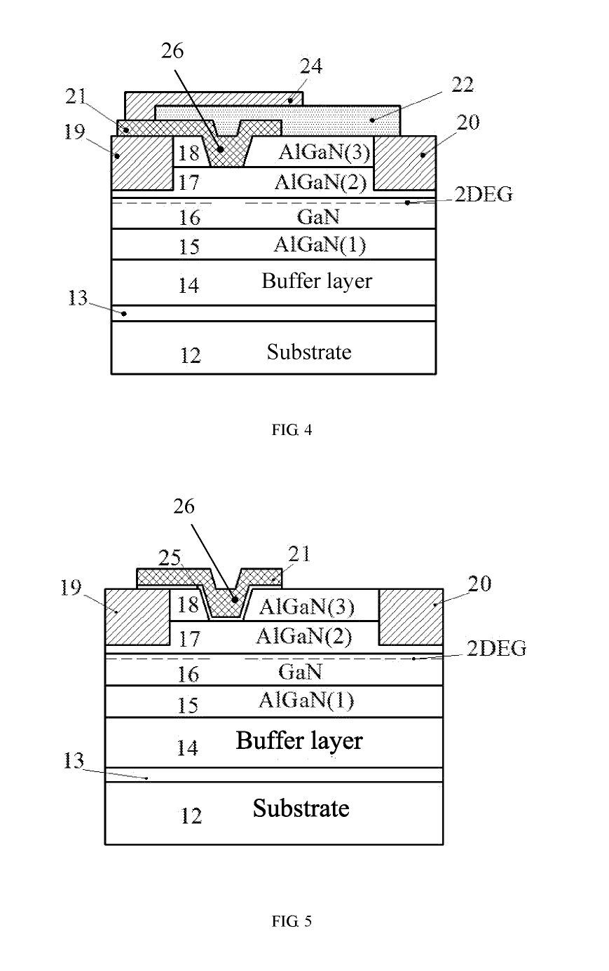

FIG. 4 is a schematic structural view of a field effect diode according to a fourth embodiment of the present invention. The duplicated description on the same or similar elements as those in the first embodiment will not be repeated.

As shown in FIG. 4, an insulating layer 22 is further formed on the second barrier layer 18 and a part of the Schottky electrode 21, and a field plate 24 covering a part of the insulating layer 21 is formed on the anode. This structure can optimize the concentration distribution of electric field lines at an edge of a side of the Schottky electrode 21 adjacent to the anode ohmic contact electrode 19, and reduce the electric field peak at an edge of the anode, thereby improving the breakdown voltage of the diode.

FIG. 5 is a schematic structural view of a field effect diode according to a fifth embodiment of the present invention. The duplicated description on the same or similar elements as those in the first embodiment will not be repeated.

As shown in FIG. 5, an insulating dielectric layer 25 is formed on a lower surface of the Schottky electrode 21. That is, the insulating dielectric layer 25 is formed between the Schottky electrode 21 and the second insulating layer 18 and the groove 26 formed in the second insulating layer 18, so that a reverse leakage current of the Schottky electrode can be reduced effectively. When the diode is reverse biased, electrons need to cross the barrier formed by the insulating dielectric layer 25 to form the reverse leakage current on the Schottky electrode, so that the leakage current of the diode according to this embodiment is lower than that according to the first embodiment.

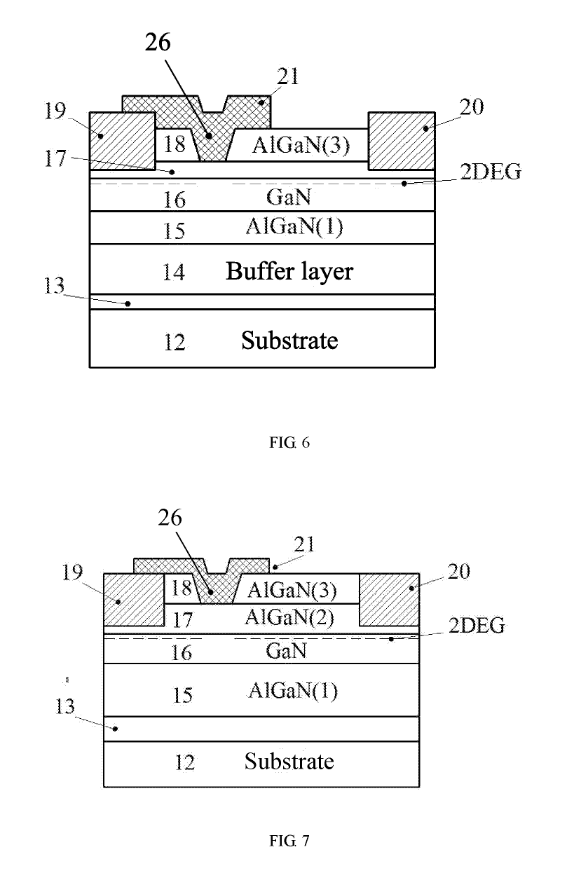

FIG. 6 is a schematic structural view of a field effect diode according to a sixth embodiment of the present invention. The duplicated description on the same or similar elements as those in the first embodiment will not be repeated.

As shown in FIG. 6, compared with the first embodiment, the first barrier layer 17 of the diode according to this embodiment has a smaller thickness, e.g., less than 15 nm, so that the resistance of the diode can be further reduced. When the diode is forward biased, a current can flow vertically through the first barrier layer 17 from the Schottky electrode 21. Sine there are two current paths, i.e., the horizontal 2DEG and the vertical Schottky diode, the forward voltage drop of the diode is further reduced, the saturation current density of the diode is increased and the power consumption of the diode is reduced.

FIG. 7 is a schematic structural view of a field effect diode according to a seventh embodiment of the present invention. The duplicated description on the same or similar elements as those in the first embodiment will not be repeated.

As shown in FIG. 7, compared with the first embodiment, there is no buffer layer in the diode according to this embodiment. Instead, the back barrier layer 15 plays the role of the buffer layer. In this case, the back barrier layer 15 has a thickness of 1-3.5 μm. By introducing a thick back barrier layer 15, the reverse leakage current is reduced and the processing is simplified.

Compared with the prior art, when the field effect diode according to an embodiment of the present invention is forward biased, the 2DEG will be induced at the part of the interface between the channel layer and the first barrier layer under the groove by applying a low bias voltage to the anode. Since the diode is turned-on in the horizontal direction by the 2DEG with high concentration and high mobility, the diode has a low forward voltage drop and a low on-resistance. When the field effect diode according to an embodiment of the present invention is reverse biased, the channel is blocked since the 2DEG under the groove is depleted completely, so that the electrons cannot flow between the cathode and the anode under a reverse bias voltage, which lowers the reverse leakage current.

In addition, the back barrier layer with good crystal quality can form a barrier with the channel layer thereon. Due to the existence of the barrier, electrons are difficult to enter into the back barrier layer from the channel layer when the diode is reverse biased, which cuts off the leakage current of the buffer layer of the diode, so that the reverse leakage current of the field effect diode is maintained at a relatively low level. Therefore, the ability of the diode to withstand a reverse voltage is increased, which increases the reverse breakdown voltage of the diode.

Furthermore, according to an embodiment of the present invention, the Schottky electrode in the groove has an inclination. When the diode is reverse biased, the distribution of electric field lines at an edge of the anode metal can be modulated, the electric field peak at the edge of the anode can be reduced, thereby improving the breakdown voltage of the diode.

It will be understood that the embodiments described herein should be considered in a descriptive sense only and not for purposes of limitation. Descriptions of features or aspects within each embodiment should typically be considered as available for other similar features or aspects in other embodiments.

While one or more embodiments of the present invention have been described with reference to the figures, it will be understood by those of ordinary skill in the art that various changes in form and details may be made therein without departing from the spirit and scope of the present invention as defined by the following claims and their equivalents.

What is claimed is:

1. A field effect diode, comprising:
a substrate;
a nucleation layer located on the substrate;
a back barrier layer located on the nucleation layer;
a channel layer located on the back barrier layer;
a first barrier layer located on the channel layer;
a second barrier layer located on the first barrier layer; and
an anode and a cathode located on the second barrier layer,
wherein a groove is formed in the second barrier layer, the cathode is made of a first ohmic contact electrode, the anode is made of a composite structure comprising a second ohmic contact electrode and a Schottky electrode which is located in the groove and has a short circuit connection with the second ohmic contact electrode;
wherein two-dimensional electron gas is formed at an interface between the first barrier layer and the channel layer except for a part of the interface under the groove when a reverse bias voltage or no external voltage is applied to the field effect diode, and is formed at all parts of the interface when a forward bias voltage is applied to the field effect diode.

2. The field effect diode of claim 1, wherein each of the back barrier layer, the first barrier layer and the second barrier layer is formed of AlGaN, the channel layer is formed of GaN, difference between an Al component content of the back barrier layer and that of the first barrier layer is zero or no more than 5%, an Al component content of the second barrier layer is higher than that of the back barrier layer and that of the first barrier layer.

3. The field effect diode of claim 2, wherein the Al component content of the back barrier layer is 10%-15%, the Al component content of the first barrier layer is 10%45%, and the Al component content of the second barrier layer is 20%-40%.

4. The field effect diode of claim 1, wherein a sidewall of the groove has an inclination.

5. The field effect diode of claim 1, wherein a depth of the groove is equal to a thickness of the second barrier layer.

6. The field effect diode of claim 1, further comprising a passivation layer located on the second barrier layer.

7. The field effect diode of claim 1, further comprising an etching stop layer between the first barrier layer and the second barrier layer,
wherein the etching stop layer has an etching rate lower than that of the first barrier layer.

8. The field effect diode of claim 1, further comprising an insulating layer located on the second barrier layer and a part of the Schottky electrode, and a field plate which is located on the anode and covers a part of the insulation layer.

9. The field effect diode of claim 1, further comprising an insulating dielectric layer formed on a lower surface of the Schottky electrode.

10. The field effect diode of claim 1, wherein the first barrier layer has a thickness less than 15 nm.

11. The field effect diode of claim 1, wherein the back barrier layer has a thickness of 1-3.5 μm.

12. The field effect diode of claim 1, further comprising a buffer layer between the nucleation layer and the back barrier layer.

13. The field effect diode of claim 12, wherein the buffer layer has a thickness of 1-3.5 μm, the back barrier layer has a thickness of 50-100 nm, the channel layer has a thickness of 15-35 nm, the first barrier layer has a thickness of 15-45 nm, and the second barrier layer has a thickness of 25-40 nm.

14. A method of manufacturing a field effect diode, comprising:
preparing a substrate;
forming a nucleation layer on the substrate;
forming a back barrier layer on the nucleation layer;
forming a channel layer on the back barrier layer;
forming a first barrier layer on the channel layer;
forming a second barrier layer on the first barrier layer and a groove in the second barrier layer; and
forming an anode and a cathode on the second barrier layer, the cathode being made of a first ohmic contact electrode, the anode being made of a composite structure comprising a second ohmic contact electrode and a Schottky electrode which is located in the groove and has a short circuit connection with the second ohmic contact electrode,
wherein two-dimensional electron gas is formed at an interface between the first barrier layer and the channel layer except for a part of the interface under the groove when a reverse bias voltage or no external voltage is applied to the field effect diode, and is formed at all parts of the interface when a forward bias voltage is applied to the field effect diode.

15. The method of claim 14, wherein each of the back barrier layer, the first barrier layer and the second barrier layer is formed of AlGaN, the channel layer is formed of GaN, difference between an Al component content of the back barrier layer and that of the first barrier layer is zero or no more than 5%, an Al component content of the second barrier layer is higher than that of the back barrier layer and that of the first barrier layer.

16. The method of claim 15, wherein the Al component content of the back barrier layer is 10%-15%, the Al component content of the first barrier layer is 10%-15%, and the Al component content of the second barrier layer is 20%-40%.

17. The method of claim 14, wherein a sidewall of the groove has an inclination, and a depth of the groove is equal to a thickness of the second barrier layer.

18. The method of claim 14, further comprising forming a passivation layer on the second barrier layer.

19. The method of claim 14, further comprising forming an etching stop layer having an etching rate lower than that of the first barrier layer on the first barrier layer.

20. The method of claim 14, further comprising forming a buffer layer on the nucleation layer.
